(19) United States
(12) Patent Application Publication
(10) Pub. No.: US 2015/0069346 A1
(43) Pub. Date: Mar. 12, 2015

(54) ORGANIC LIGHT EMITTING DIODE DISPLAY AND MANUFACTURING METHOD THEREOF

(71) Applicant: Samsung Display Co., Ltd., Yongin-city (KR)

(72) Inventors: Sang Woo KIM, Cheonan-si (KR); Ju Yeop SEONG, Cheonan-si (KR)

(73) Assignee: Samsung Display Co., Ltd., Yongin-city (KR)

(21) Appl. No.: 14/282,887

(22) Filed: May 20, 2014

(30) Foreign Application Priority Data
Sep. 9, 2013 (KR) 10-2013-0107983

(51) Int. Cl. H01L 51/52; H01L 51/56; H01L 27/32

(52) U.S. Cl. CPC H01L 51/5293; H01L 27/323; H01L 51/56; H01L 2251/558
USPC 257/40; 438/29

(57) ABSTRACT

An organic light emitting diode (OLED) display includes a display substrate, a display element layer disposed on the display substrate and comprising a plurality of pixels, a thin film encapsulation layer disposed on the display substrate and the display element layer, a retardation film disposed on the thin film encapsulation layer, a capacitive pattern disposed on the retardation film, a polarizing plate disposed on the capacitive pattern, and a window disposed on the polarizing plate.

### CROSS REFERENCE TO RELATED APPLICATION

This application claims priority from and the benefit of Korean Patent Application No. 10-2013-0107983, filed on Sep. 9, 2013, which is hereby incorporated by reference for all purposes as if fully set forth herein.

### BACKGROUND

1. Field

Exemplary embodiments of the present invention relate to an organic light emitting diode (OLED) display and a manufacturing method thereof.

2. Discussion of the Background

In general, a touch panel is a device for an image display device, e.g., an organic light emitting diode (OLED) display that recognizes a contact location corresponding to a character or an image displayed on a screen thereof, touched by a user hand or an object.

Particularly, an electrostatic capacity touch panel display device is manufactured by forming a capacitive pattern at an upper portion of a display panel thereof, and attaching a retardation film and a polarizing plate thereon, or by attaching the retardation film and the polarizing plate on an upper portion of the display panel, and attaching the capacitive pattern layer thereon. For the retardation film, a λ/4 retardation film is used to change linear polarization into circular polarization or change circular polarization into linear polarization.

However, the conventional methods have a problem of increasing an entire thickness of the display panel by forming an additional layer of the capacitive pattern at the upper portion. Further, the light emitted from an organic light emitting element may be absorbed by an electrode such as indium tin oxide (ITO) or the like which is additionally disposed at a front surface of an encapsulation film, thereby reducing the luminance of emitted light.

The above information disclosed in this Background section is only for enhancement of understanding of the background of the described technology and therefore it may contain information that does not form the prior art that is already known in this country to a person of ordinary skill in the art.

### SUMMARY

Exemplary embodiments of the present invention provide an organic light emitting diode (OLED) display having a touch function and a manufacturing method thereof, having advantages of reducing thickness and weight of the OLED display and improving screen visibility.

Additional features of the invention will be set forth in the description which follows, and in part will be apparent from the description, or may be learned by practice of the invention.

An exemplary embodiment provides an OLED display including a display substrate, a display element layer disposed on the display substrate and comprising a plurality of pixels, a thin film encapsulation layer disposed on the display substrate and the display element layer, a retardation film disposed on the thin film encapsulation layer, a capacitive pattern disposed on the retardation film; a polarizing plate disposed on the capacitive pattern, and a window disposed on the polarizing plate.

An exemplary embodiment also provides a manufacturing method of an OLED display, including attaching a retardation film on a base substrate, forming a capacitive pattern on the retardation film, detaching the substrate and the retardation film from each other, and attaching a polarizing plate on the capacitive pattern.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a cross-sectional view showing an organic light emitting diode (OLED) display in accordance with an exemplary embodiment.

FIG. 2 is a cross-sectional view schematically showing a structure of the OLED display in which a retardation film, a capacitive pattern, and a polarizing plate are stacked in accordance with the present exemplary embodiment.

FIG. 3 shows an equivalent circuit of the OLED display in accordance with the present exemplary embodiment.

FIG. 4 is a flowchart showing a manufacturing method of the OLED display in accordance with the present exemplary embodiment.

FIGS. 5A, 5B, 5C, and 5D are stepwise cross-sectional views showing the manufacturing method of the OLED display in accordance with the present exemplary embodiment.

FIG. 6 is a cross-sectional view schematically showing a structure of the OLED display in which a retardation film, a capacitive pattern, and a polarizing plate are stacked in accordance with another exemplary embodiment.

FIG. 7 is a cross-sectional view schematically showing a structure of the OLED display in which a retardation film, a capacitive pattern, and a polarizing plate are stacked in accordance with yet another exemplary embodiment.

### DETAILED DESCRIPTION

Hereinafter, an exemplary embodiment will be described in detail with reference to the attached drawings such that the present invention can be easily put into practice by those skilled in the art. As those skilled in the art would realize, the described embodiments may be modified in various different ways, all without departing from the spirit or scope of the present invention.

In addition, in various exemplary embodiments, the same constituent elements are denoted by the same reference numerals and are representatively described in an exemplary embodiment, and different elements from the elements of the exemplary embodiment are described in other exemplary embodiments.

The drawings are schematic and are not illustrated in accordance with a scale. The relative sizes and ratios of the parts in the drawings are exaggerated or reduced for clarity and convenience in the drawings, and the arbitrary sizes are only exemplary and are not limiting. The same structures, elements, or parts illustrated in no less than two drawings are denoted by the same reference numerals in order to represent similar characteristics. When a part is referred to as being “on” another part, it can be directly on the other part or intervening parts may also be present. In contrast, when an element or layer is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Exemplary embodiments are illustrated in detail. As a result, various modifications are expected to be made. Therefore, the exemplary embodiments are not limited to a specific shape of an illustrated region, but, for example, include changes in shape in accordance with manufacturing.

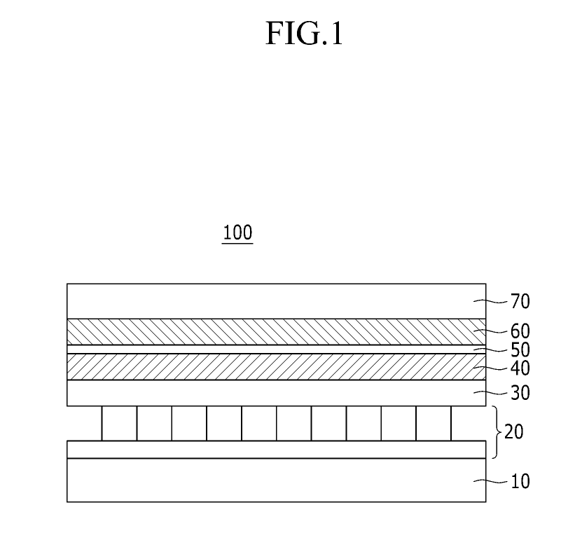

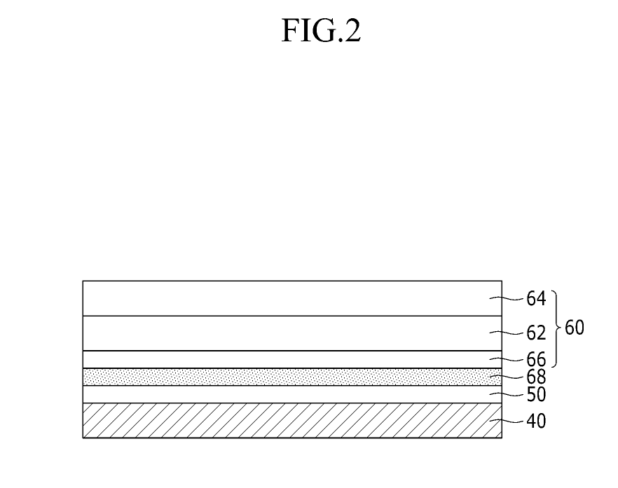

An organic light emitting diode (OLED) display in accordance with an exemplary embodiment will now be described with reference to FIG. 1 and FIG. 2.

FIG. 1 is a cross-sectional view showing an organic light emitting diode (OLED) display in accordance with an exemplary embodiment, and FIG. 2 is a cross-sectional view schematically showing a structure of the OLED display in which a retardation film, a capacitive pattern, and a polarizing plate are stacked in accordance with the present exemplary embodiment.

Referring to FIG. 1 and FIG. 2, the OLED display 100 in accordance with the present exemplary embodiment includes a display substrate 10, a display element layer 20, a thin film encapsulation layer 30, a retardation film 40, a capacitive pattern 50, a polarizing plate 60, and a window 70.

The display substrate 10 may be a liquid crystal display panel including a liquid crystal, or an organic light emitting panel including an organic light emitting unit. Alternatively, the display substrate 10 may be a transparent flexible substrate such as a polymer film.

The display element layer 20 is formed on the display substrate 10 and includes an element region in which an active element such as a thin film transistor (TFT) is formed and a light emitting region in which an emission layer is formed. The element region and the light emitting region may be located separately from each other or overlapping each other.

The thin film encapsulation layer 30 is formed on the display element layer 20 facing the display substrate 10. The thin film encapsulation layer 30 can protect the display element layer 20 against oxygen and moisture from the outside.

The retardation film 40 is provided on the thin film encapsulation layer 30. The retardation film 320 may be a λ/4 retardation film to change linear polarization into circular polarization or change circular polarization into linear polarization. The retardation film 40 may be a birefringence film, an alignment film of a liquid crystal polymer, or a film supported with the alignment layer of the liquid crystal polymer, formed by stretching the film made of at least one polymer of a polycarbonate, a polyvinyl alcohol, a polystyrene, a polymethylmethacrylate, a polypropylene, a polyolefin, a polyarylate, and a polyamide. Alternatively, the retardation film 40 may be formed of cyclic olefin polymer (COP), such as a Zeonor resin or an Arton resin.

The capacitive pattern 50 may be formed on the retardation film 40. The capacitive pattern 50 may include a plurality of pattern units disposed in a matrix pattern, but is not limited thereto.

The polarizing plate 60 is provided on the retardation film 40 on which the capacitive pattern 50 is formed. The polarizing plate 60 may include a polarizer layer 62 and an upper support 64 formed on the polarizer layer 62. The polarizing plate 60 may further include a lower support 66 formed below the polarizer layer 62. The polarizer layer 62 may be formed of polyvinyl alcohol (PVA), and the lower support 66 and the upper support 64 may be formed of triacetyl cellulose (TAC).

The window 70 is attached on the polarizing plate 60. The window 70 may be made of a transparent material to cover and protect the display element layer 20.

The OLED display 100 may further include an adhesion layer 68 between the polarizing plate 60 and the capacitive pattern 50. The adhesion layer 68 may be a pressure sensitivity adhesive layer (PSA) and be formed of a film including an adhesive agent to perform an adhering operation in response to a pressure transferred from the outside. The adhesive agent may include an acryl-based or rubber-based adhesive agent that has a refractive index in the range of 1.46 to 1.52, or an adhesive agent that includes particulates such as zirconia and the like in order to adjust the refractive index of the adhesive agent.

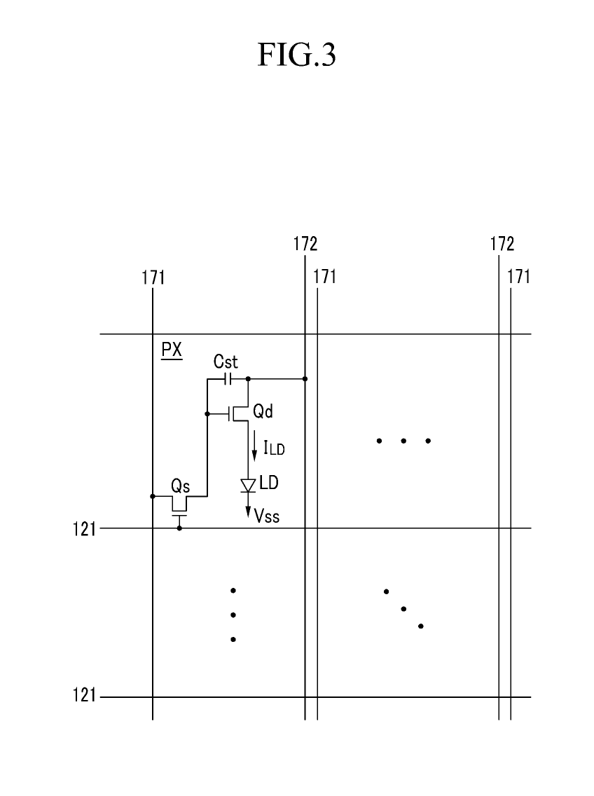

FIG. 3 shows an equivalent circuit of the OLED display in accordance with the present exemplary embodiment.

Referring to FIG. 3, the display element layer 20 includes a plurality of signal lines 121, 171, and 172, and a plurality of pixels PX connected to the signal lines 121, 171, and 172 and arranged substantially in a matrix shape.

The signal lines 121, 171, and 172 include a plurality of gate lines 121 transmitting a gate signal (or, scan signal), a plurality of data lines 171 transmitting a data signal, and a plurality of driving voltage lines 172 transmitting a driving voltage. The gate lines 121 are extended in a row direction and almost parallel with each other, and the data lines 171 and the driving voltage lines 172 are approximately arranged in a column direction and almost parallel with each other.

Each pixel PX includes a switching thin film transistor Qs, a driving thin film transistor Qd, a storage capacitor Cst, and an organic light emitting diode (OLED) LD.

The switching thin film transistor Qs includes a control terminal, an input terminal, and an output terminal. The control terminal is connected to the gate line 121, the input terminal is connected to the data line 171, and the output terminal is connected to the control terminal of the driving thin film transistor Qd. The switching thin film transistor Qs transmits a data signal applied to the data line 171 to the driving thin film transistor Qd in response to a scan signal applied to the gate line 121.

The driving thin film transistor Qd includes a control terminal, an input terminal, and an output terminal. The control terminal is connected to the output terminal of the switching thin film transistor Qs, the input terminal is connected to the driving voltage line 172, and the output terminal is connected to the anode of the OLED LD. The driving thin film transistor Qd transfers an output current I_{LD} of which magnitude varies depending on a voltage between the control terminal and the output terminal thereof.

The capacitor Cst is connected between the control terminal and the input terminal of the driving thin film transistor Qd. The capacitor Cst charges the data signal applied to the control terminal of the driving thin film transistor Qd and maintains the charge of the data signal after the switching thin film transistor Qs is turned off.

The OLED LD includes an anode connected to the output terminal of the driving thin film transistor Qd and a cathode connected to a common voltage Vss. The OLED LD emits light with intensity corresponding to the output current I_{LD} of the thin film transistor Qd to display an image.

The switching thin film transistor Qs and the driving thin film transistor Qd are n-channel field effect transistors (FETs). However, at least one of the switching thin film transistor Qs and the driving thin film transistor Qd may be a p-channel field effect transistor. Further, the thin film transistors Qs and Qd, the capacitor Cst, and the OLED LD may have different interconnection.

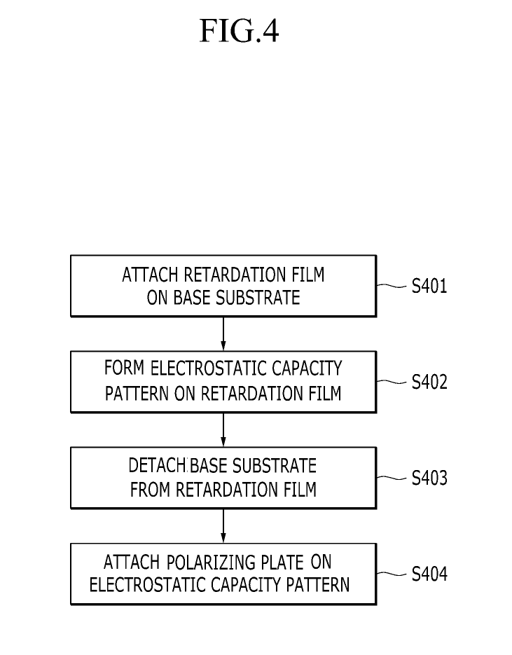

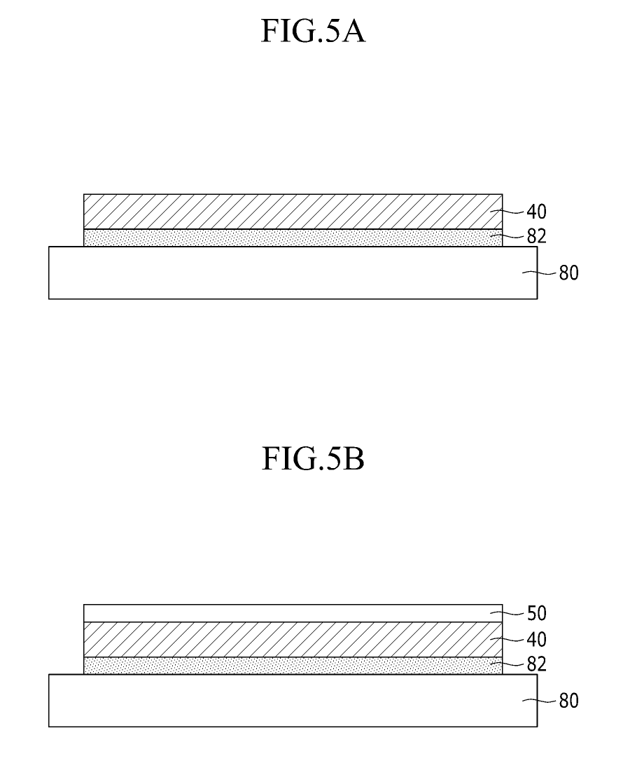

FIG. 4 is a flowchart showing a manufacturing method of the OLED display in accordance with the present exemplary embodiment, and FIG. 5A to FIG. 5D are stepwise cross-sectional views showing the manufacturing method of the OLED display in accordance with the present exemplary embodiment.

Referring to FIG. 4 to FIG. 5D, a retardation film 40 is first attached on a base substrate 80 (S401, see FIG. 5A). The base substrate 80 may be made of a bare glass material, and the retardation film 40 is attached on the base substrate 80 by using an adhesive 82.

Thereafter, a capacitive pattern 50 is formed on the retardation film 40 (S402, see FIG. 5B). The capacitive pattern 50 may be obtained by forming an indium tin oxide (ITO) pattern and a plurality of openings at locations corresponding to the pixels of the organic light emitting element. The capacitive pattern 50 may include a plurality of pattern units disposed in a matrix pattern, but is not limited thereto.

Next, the base substrate 80 is detached from the retardation film 40 (S403, see FIG. 5C). Then, a polarizing plate 60 is attached on the capacitive pattern 50 by using an adhesion layer 68 (S404, see FIG. 5D). A protection film (not shown) may be attached beneath the retardation film 40 to prevent damage to the retardation film 40 caused by scratches and the like. The protective film may be an acetate-based resin such as triacetyl cellulose or a triacetyl cellulose film with surface saponified with an alkali and the like. The adhesion layer 68 may include an acryl-based or rubber-based adhesive agent that has a refractive index ranging from 1.46 to 1.52, or an adhesive agent that includes particulates such as zirconia and the like in order to adjust the refractive index of the adhesive agent.

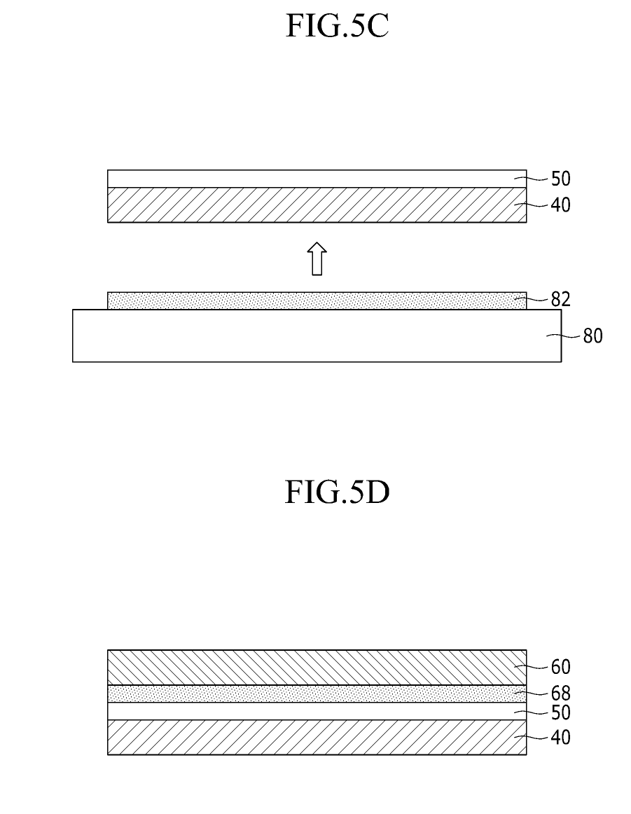

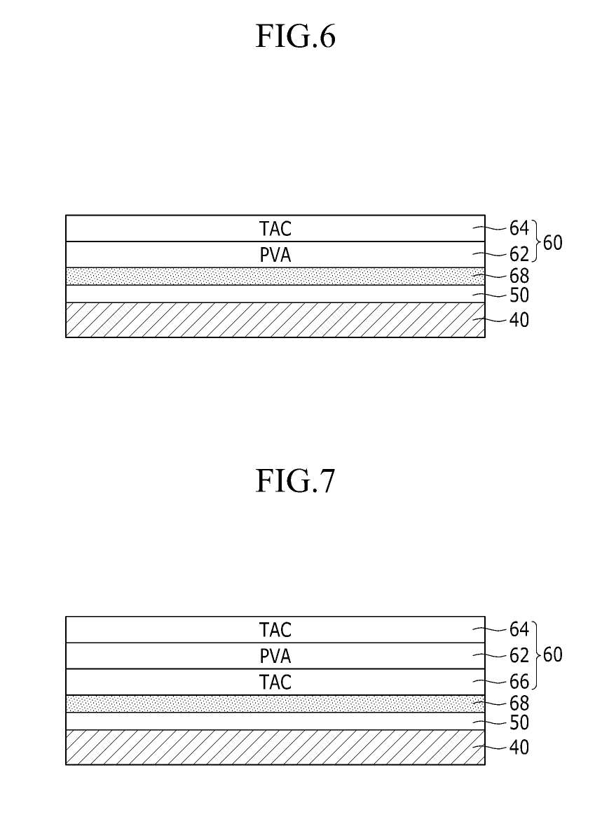

FIG. 6 is a cross-sectional view schematically showing a structure of the OLED display in which a retardation film, a capacitive pattern, and a polarizing plate are stacked in accordance with another exemplary embodiment, and FIG. 7 is a cross-sectional view schematically showing a structure of the OLED display in which a retardation film, a capacitive pattern, and a polarizing plate are stacked in accordance with yet another exemplary embodiment.

Referring to FIG. 6 and FIG. 7, the polarizing plate 60 may include a polarizer layer 62 and an upper support 64 formed on the polarizer layer 62, or may include the polarizer layer 62, the upper support 64 formed on the polarizer layer 62, and a lower support 66 formed below the polarizer layer 62. The polarizer layer 62 may be formed of polyvinyl alcohol (PVA), and the lower support 66 and the upper support 64 may be formed of triacetyl cellulose (TAC).

According to the OLED display and the manufacturing method thereof in accordance with the exemplary embodiments, the capacitive pattern can be directly formed on the retardation film to thereby reduce thickness and weight of the OLED display and omit a capacitive pattern layer. Thus, light transmittance and screen visibility can be increased, and manufacturing cost can be reduced.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode (OLED) display, comprising:
a display substrate;
a display element layer disposed on the display substrate and comprising a plurality of pixels;
a thin film encapsulation layer disposed on the display substrate and the display element layer;
a retardation film disposed on the thin film encapsulation layer;
a capacitive pattern disposed on the retardation film;
a polarizing plate disposed on the capacitive pattern; and
a window disposed on the polarizing plate.

2. The OLED display of claim 1, wherein the retardation film is a λ/4 retardation film.

3. The OLED display of claim 1, wherein the retardation film comprises a λ/4 retardation film and a λ/2 retardation film provided on the λ/4 retardation film.

4. The OLED display of claim 1, wherein the retardation film comprises a cyclic olefin polymer (COP).

5. The OLED display of claim 1, wherein the polarizing plate comprises a polarizer layer and an upper support formed on the polarizer layer.

6. The OLED display of claim 5, wherein the polarizing plate further comprises a lower support disposed under the polarizer layer.

7. The OLED display of claim 5, wherein the polarizer layer is disposed of polyvinyl alcohol (PVA).

8. The OLED display of claim 5, wherein the upper support is disposed of triacetyl cellulous (TAC).

9. The OLED display of claim 6, wherein the lower support is disposed of triacetyl cellulous (TAC).

10. The OLED display of claim 1, further comprising an adhesion layer disposed between the polarizing plate and the capacitive pattern.

11. A manufacturing method of an OLED display, the method comprising:
attaching a retardation film on a base substrate;
forming a capacitive pattern on the retardation film;
detaching the substrate and the retardation film from each other; and
attaching a polarizing plate on the capacitive pattern.

12. The manufacturing method of claim 11, wherein the polarizing plate comprises a polarizer layer and an upper support disposed on the polarizer layer.

13. The manufacturing method of claim 12, wherein the polarizing plate further comprises a lower support disposed below the polarizer layer.

14. The manufacturing method of claim 12, wherein the polarizer layer comprises polyvinyl alcohol (PVA).

15. The manufacturing method of claim 12, wherein the upper support comprises triacetyl cellulous (TAC).

16. The manufacturing method of claim 13, wherein the lower support comprises triacetyl cellulous (TAC).
